(19) United States
(12) Patent Application Publication
(10) Pub. No.: US 2012/0105706 A1
(43) Pub. Date: May 3, 2012

(54) PHOTOGRAPHIC MODULES AND METHODS OF FORMING THE SAME

(75) Inventor: Yung-Cheol KONG, Cheonan-si (KR)

(73) Assignee: Samsung Electronics Co., Ltd., Suwon-si (KR)

(21) Appl. No.: 13/347,921

(22) Filed: Jan. 11, 2012

Related U.S. Application Data
(62) Division of application No. 12/624,551, filed on Nov. 24, 2009.

(30) Foreign Application Priority Data
Nov. 24, 2008 (KR) 2008-117110

(51) Int. Cl. H01L 31/0232; H04N 5/225

(52) U.S. Cl. 348/340; 257/432; 257/E31.127; 348/E05.028

(57) ABSTRACT

Methods of forming camera modules include forming a chip structure including a molding pattern surrounding a chip and sidewalls of the chip. A lens module is formed, and the lens module is coupled to an upper part of the chip structure.

### CROSS-REFERENCE TO RELATED APPLICATIONS

This application is a divisional application of Ser. No. 12/624,551 filed Nov. 24, 2009 in the U.S. Patent and Trademark Office, which claims the benefit of Korean Patent Application No. 10-2008-0117110, filed on Nov. 24, 2008, in the Korean Intellectual Property Office, the disclosure of which is incorporated herein in its entirety by reference.

### BACKGROUND

1. Field of the Invention

Example embodiments relate to photographic modules, methods of forming photographic modules, and more particularly, to methods capable of decreasing sizes of photographic modules.

2. Description of the Related Art

Recently, with the development of the computer and telecommunication industries, demand for camera modules including improved image sensor chips is growing in a variety of fields including digital cameras, camcorders, personal communication systems (PCSs), gaming systems, security cameras, medical micro cameras, robots, etc.

### SUMMARY

Example embodiments provide photographic modules and methods of forming photographic modules.

Additional aspects and utilities of the present general inventive concept will be set forth in part in the description which follows and, in part, will be obvious from the description, or may be learned by practice of the general inventive concept.

Features and/or utilities of the present general inventive concept may be realized by a method of forming a camera module including forming a chip structure. The chip structure may include a chip and a molding pattern surrounding sidewall of the chip. A lens module may be coupled to an upper part of the chip structure.

The lens module may include the lens structure and a housing at least covering a sidewall of the lens structure.

The molding pattern may have one or more slots and the lens module may have one or more prominences at positions corresponding to the slots. The prominences may be coupled to the slots when the lens module is coupled to the chip structure.

Forming the chip structure may include forming chips spaced apart from each other, forming molding layers between the chips and connecting the chips, and forming molding patterns surrounding sidewalls of the chips by cutting the molding layer between the chips.

Features and/or utilities of the present general inventive concept may also be realized by a method of forming a camera module including forming a wafer including image sensing regions. A plurality of chips may be formed by cutting the wafer. A chip rearrangement process may be performed such that the chips are spaced apart from each other. A molding layer may be formed between the chips and the chips may be connected to each other. The molding layer between the chips may be cut so that molding patterns surrounding sidewalls of the chips are formed.

The method may further include, before cutting the molding layer, forming lens structures spaced apart from each other, forming a housing structure between the lens structures and connecting the lens structures, coupling the lens structures onto the connected chips, and cutting the housing structure between the lens structures during cutting the molding layer.

The molding layer between the chips may be formed to have slots, the housing structure may be formed to have housing prominences, the connected lens structures may be coupled to the connected chips such that the housing prominences are coupled to the slots, and the housing structure and the molding layer may be cut to cross between the housing prominences and the slots.

Forming the molding layer between the chips spaced apart from each other may include rearranging the chips to be spaced apart from each other on a molding substrate, and filling a molding material layer between the rearranged chips. The molding substrate may include molding prominences between the rearranged chips so that the molding layer between the chips has slots at positions corresponding to the molding prominences.

The method may further include, before cutting the molding layer, forming lens structures spaced apart from each other, forming a housing structure between the lens structures and connecting the lens structures, forming housings surrounding sidewalls of the lens structures by cutting the housing structure between the lens structures, the lens structures and the housings being defined as a lens module, and coupling the lens modules onto the connected chips.

Features and/or utilities of the present general inventive concept may also be realized by a method of forming a camera module including forming a chip wafer including image sensing regions. A lens wafer may be formed on the chip wafer. Lens chip structures may be formed by cutting the chip wafer and the lens wafer. A rearrangement process for spacing the lens chip structures apart from each other may be performed. A molding layer may be formed between the lens-chip structures spaced apart from each other. Molding patterns surrounding sidewalls of the lens-chip structures may be formed by cutting the molding layer.

Features and/or utilities of the present general inventive concept may also be realized by a method of forming a photographic module including mounting a lens layer onto a first surface of a semiconductor chip module having a semiconductor chip including an image-sensing region and a molding layer around sides of the semiconductor chip.

The semiconductor chip may include a semiconductor chip wafer having the image-sensing region and a transparent layer mounted on the first surface of the semiconductor chip wafer, such that the surface of the transparent layer opposite the semiconductor chip wafer is defined as the first surface of the semiconductor chip.

The at least one semiconductor chip may include a plurality of semiconductor chips on a semiconductor chip wafer, and the method may further include cutting the semiconductor chip wafer and the lens layer to form a plurality of individual photographic modules, each photographic module including a semiconductor chip and a lens.

The first surface of the semiconductor chip may be capable of transmitting light to the image-sensing region and may be defined as an upper surface, a lower surface is located opposite the upper surface, and lateral sides are located between and connect the upper surface and the lower surface. The molding layer may be located only on the lateral sides of each photographic module.

Forming the molding layer may include arranging the plurality of individual photographic modules side-by-side, separated by a space having a predetermined width, physically connecting the plurality of individual photographic modules by filling the space separating the plurality of photographic modules with a molding material, and cutting the molding material between the plurality of photographic modules.

Forming the lens layer on the transparent layer may include separating a plurality of lenses by a space having a predetermined width, filling the space between the plurality of lenses with a housing structure, and mounting the lens layer on the photographic modules by contacting the housing structure of the lens layer to the molding material between the plurality of photographic modules.

The lens layer may be cut into a plurality of individual lens modules before mounting the lens layer onto the plurality of photographic modules.

Cutting the molding material between the plurality of photographic modules may include cutting the housing structure between the plurality of lenses.

Forming a molding layer around each individual photographic module may include forming at least a first connector on a first surface of the molding material co-planar with the first surface of the semiconductor chip, the housing structure may include a second connector, and mounting the lens layer on the photographic modules may include connecting the first connector to the second connector.

Forming the first connector may include arranging the plurality of semiconductor chips side-by-side on a support surface having a protrusion corresponding to the first connector, such that the first surface of each of the semiconductor chips contacts the support surface, filling a space defined by the support surface and lateral sides of the plurality of semiconductor chips with the molding material, and removing the support surface from the plurality of semiconductor chips.

The molding layer between each two adjacent semiconductor chips may include at least two first connectors, and cutting the molding material between the plurality of photographic modules may include cutting the molding material between the at least two first connectors.

The at least one semiconductor chip may include a plurality of semiconductor chips on a semiconductor chip wafer, and the method may further include, before forming the lens layer, cutting the semiconductor chip wafer to form a plurality of semiconductor chip modules, and forming a molding layer around each semiconductor chip module. Mounting the lens layer onto the first surface of the semiconductor chip may include mounting a lens onto each semiconductor chip module that is physically disconnected from each other lens.

Forming the molding layer may include forming a first connector on a first surface of the molding layer, and mounting the lens layer onto each semiconductor chip module may include forming a housing around a lens, the housing including a second connector, and mounting the lens to the first surface of the molding layer by connecting the second connector to the first connector.

Features and/or utilities of the present general inventive concept may also be realized by a photographic module including a semiconductor chip including an image-sensing region in a first surface of the semiconductor chip, a molding material located on lateral sides of the semiconductor chip, and a lens structure mounted to the semiconductor chip.

The photographic module may further include a transparent layer located on the first surface of the semiconductor chip. The molding material may be located on lateral sides of the transparent layer.

The photographic module may further include electrical connection pads on a second surface of the semiconductor chip opposite the first surface.

The lens structure may include a lens and a housing located on the lateral sides of the lens, the housing may include a first connector, the molding material on lateral sides of the semiconductor chip may include a second connector, and the first connector may be connected to the second connector.

One of the first connector and the second connector may be a protrusion and the other of the first connector and the second connector may be a recess to receive the protrusion.

Features and/or utilities of the present general inventive concept may also be realized by a photographic module including a semiconductor chip module layer including a plurality of semiconductor chips separated from each other, each having an image-sensing region in a first surface, and a molding material filling a space between the plurality of semiconductor chips, and a lens layer mounted onto the semiconductor chip module layer, the lens layer including a plurality of lenses separated by housings. The lens layer may be mounted onto the semiconductor chip module layer such that each semiconductor chip corresponds to a single lens of the lens layer.

The molding material may include at least one first connector, the housings may include at least one second connector, and mounting the lens layer to the semiconductor chip module layer may include connecting the at least one first connector to the at least one second connector.

Each semiconductor chip may correspond to a separate at least one first connector and a separate at least one second connector.

Features and/or utilities of the present general inventive concept may also be realized by an image-capture device including a semiconductor chip including an image-sensing region in a first surface of the semiconductor chip, a molding material located on lateral sides of the semiconductor chip, a lens structure mounted to the semiconductor chip, and a controller to capture an image received by the image-sensing region.

The controller may include at least one memory device to store data corresponding to the image received by the image-sensing region and at least one processor to control at least one of the semiconductor chip and the memory device.

### BRIEF DESCRIPTION OF THE DRAWINGS

The above and/or other aspects of the present general inventive concept will become apparent and more readily appreciated from the following description of the exemplary embodiments, taken in conjunction with the accompanying drawings, in which:

FIG. 1 is a cross-sectional view of a chip wafer to form components constituting camera modules according to example embodiments;

FIGS. 2A through 2C are cross-sectional views of chip package wafers to form components constituting the camera modules according to example embodiments;

FIG. 3 is a cross-sectional view of a chip structure constituting the camera modules according to example embodiments;

FIGS. 4A, 4B and 5 are cross-sectional views of lens modules constituting camera modules according to example embodiments;

FIGS. 6A through 6C and 7 are cross-sectional views of camera modules according to example embodiments;

FIGS. 8A through 8C are cross-sectional views of camera modules according to other example embodiments; and

FIG. 9 illustrates an image capture device according to an embodiment of the present general inventive concept

### DETAILED DESCRIPTION OF THE EMBODIMENTS

Various example embodiments will now be described more fully with reference to the accompanying drawings in which some example embodiments are shown. In the drawings, the thicknesses of layers and regions may be exaggerated for clarity.

Reference will now be made in detail to the embodiments of the present general inventive concept, examples of which are illustrated in the accompanying drawings, wherein like reference numerals refer to the like elements throughout. The embodiments are described below in order to explain the present general inventive concept by referring to the figures.

Detailed illustrative embodiments of the present general inventive concept are disclosed herein. However, specific structural and functional details disclosed herein are merely representative for purposes of describing example embodiments. This general inventive concept, however, may be embodied in many alternate forms and should not be construed as limited to only example embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but on the contrary, example embodiments are to cover all modifications, equivalents, and alternatives falling within the scope of the general inventive concept. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected,” “coupled” to, or “mounted” to another element, it can be directly connected or coupled to the other element or intervening elements may be present. In contrast, when an element is referred to as being “directly connected,” “directly coupled,” or “directly mounted” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof. Spatially relative terms, such as “beneath,” “below,” “lower,” “above,” “upper” and the like, may be used herein for ease of description to describe one element or a relationship between a feature and another element or feature as illustrated in the figures. It will be understood that the spatially relative terms are intended to encompass different orientations of the device in use or operation in addition to the orientation depicted in the Figures. For example, if the device in the figures is turned over, elements described as “below” or “beneath” other elements or features would then be oriented “above” the other elements or features. Thus, for example, the term “below” can encompass both an orientation which is above as well as below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

To more specifically describe example embodiments, various aspects will be described in detail with reference to the attached drawings. However, the present general inventive concept is not limited to example embodiments described.

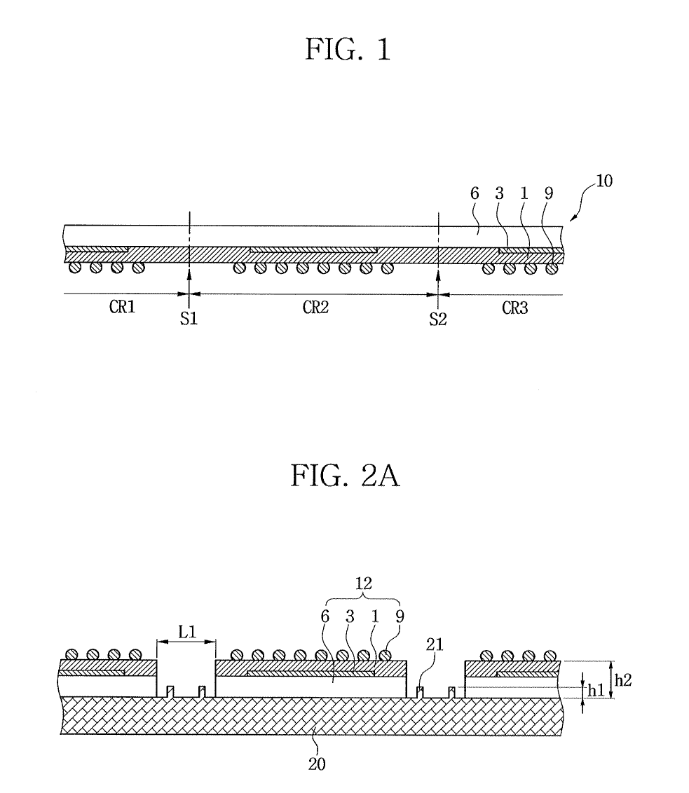

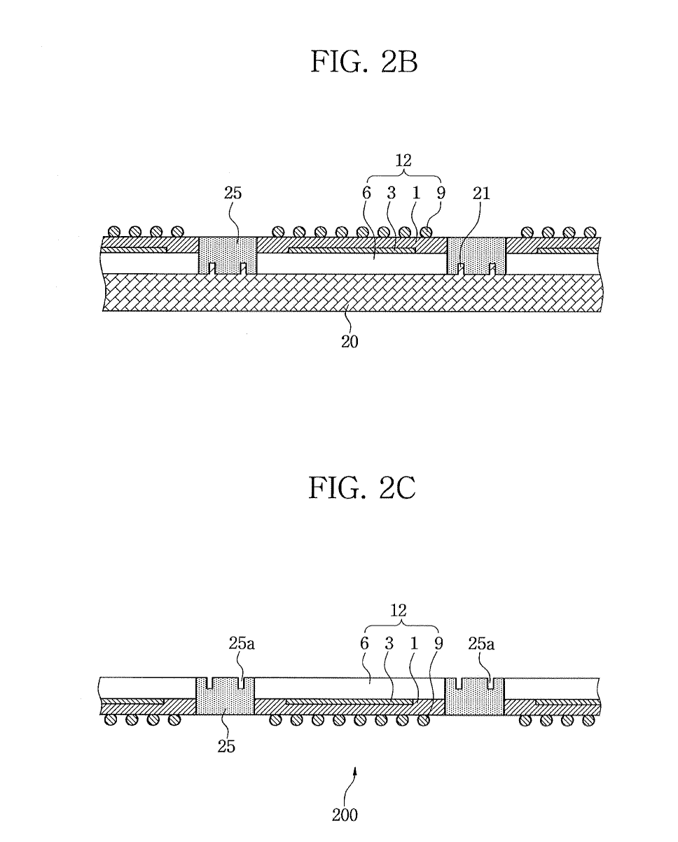

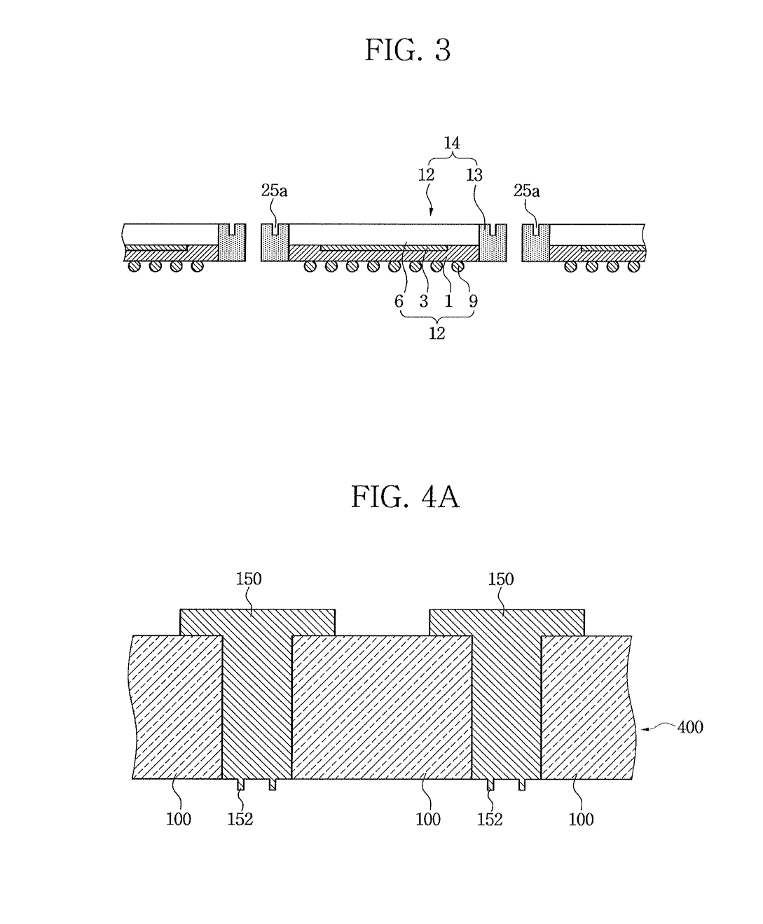

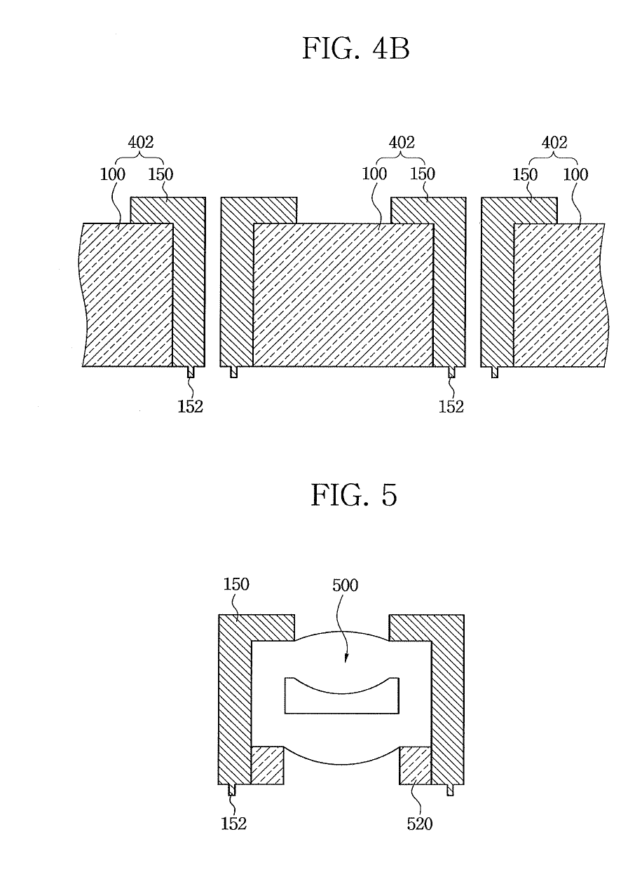

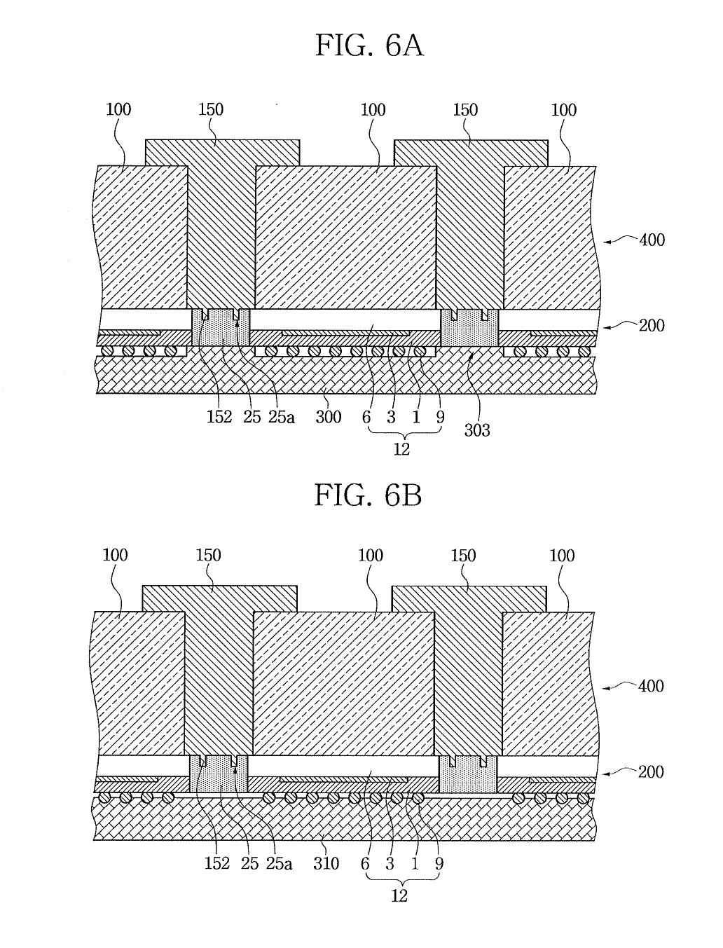

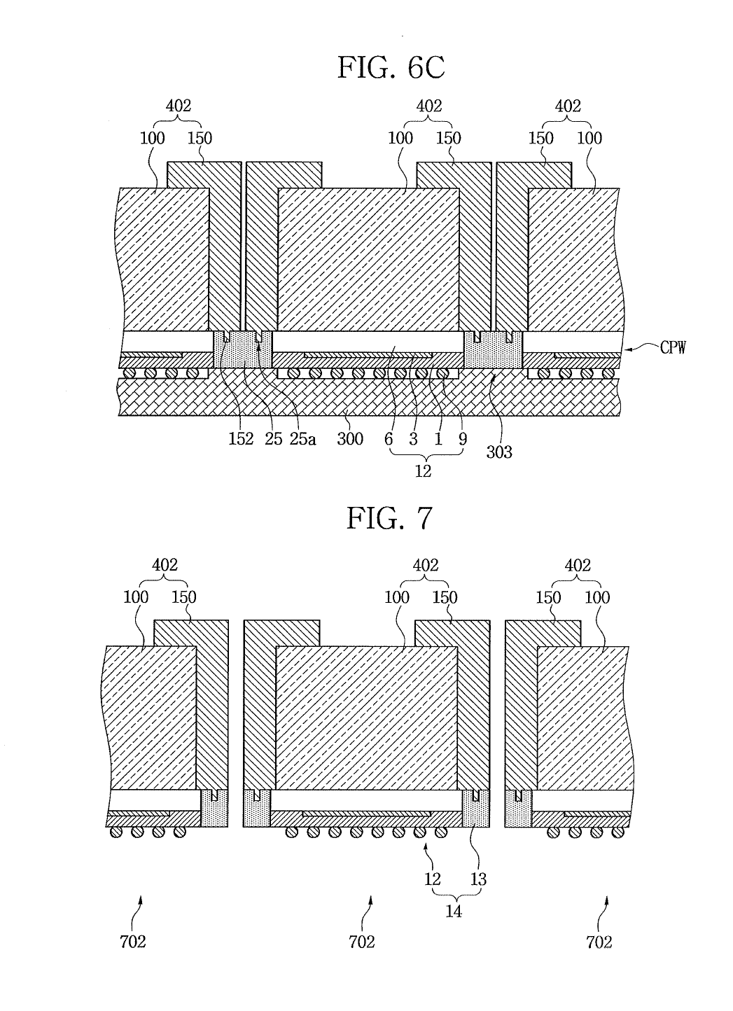

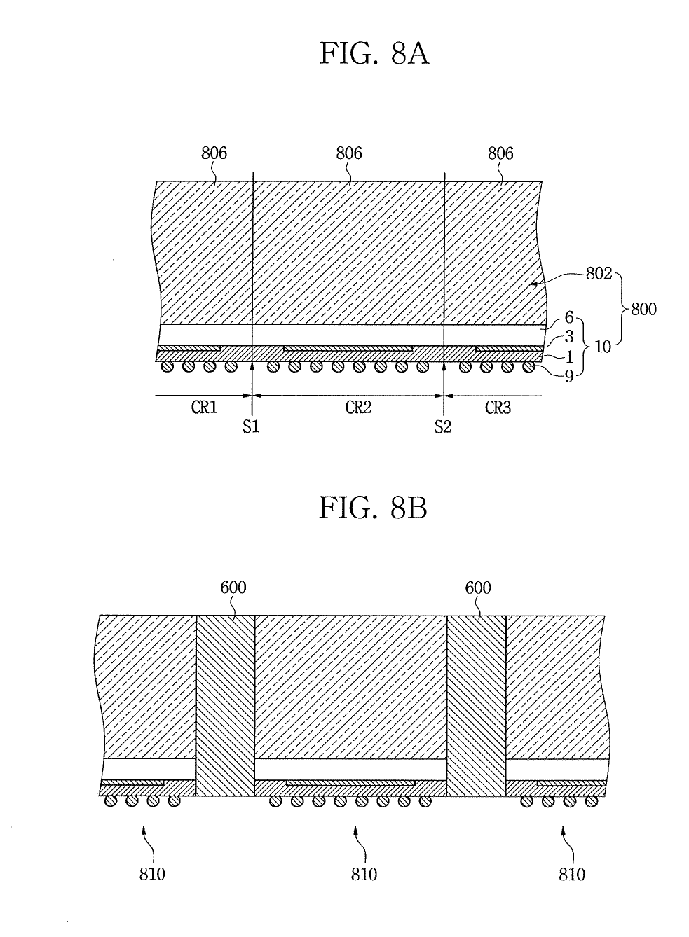

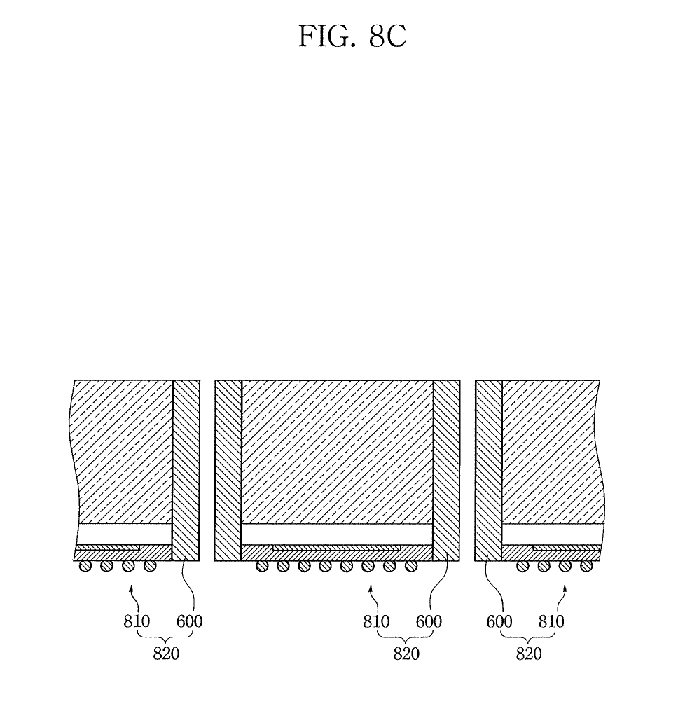

FIG. 1 is a cross-sectional view of a semiconductor chip wafer to form components of a camera module or photographic module. FIGS. 2A through 2C are cross-sectional views of a semiconductor chip package wafer to form components of the camera modules according to example embodiments. FIG. 3 is a cross-sectional view of a chip structure constituting the camera modules according to example embodiments. FIGS. 4A, 4B, and 5 are cross-sectional views of a lens module constituting the camera modules according to example embodiments, and FIGS. 6A through 6C and 7 are cross-sectional views of the camera modules according to example embodiments. FIGS. 8A through 8C are cross-sectional views of a camera module according to other example embodiments.

Hereinafter, components constituting a camera module, photographic module, or image-capture module according to example embodiments will be described with reference to FIGS. 1 through 5, and then methods of forming the camera modules using these components will be described with FIGS. 6A through 8C.

First, a chip wafer to form camera modules according to example embodiments will be described with reference to FIG. 1.

A wafer 1 having a plurality of chip regions CR1, CR2 and CR3 and sawing regions S1 and S2 between the chip regions CR1, CR2 and CR3 may be prepared. The wafer 1 may include a semiconductor material such as silicon, etc. On a first surface of the wafer 1, image sensing regions 3 including a plurality of image sensing devices may be formed. The image sensing devices may include a photoelectric conversion device, for example. The photoelectric conversion device may include a photo diode. Through electrodes an other wiring, logic elements, and circuitry (not illustrated) may be formed within the wafer 1. The through electrodes may be electronically connected to the image sensing regions and may extend from the first surface including the image sensing regions to a second surface opposite the first surface.

A transparent substrate 6 may be formed or mounted on the first surface of the wafer 1. The transparent substrate 6 may be capable of transmitting light onto the image sensing regions 3. The transparent substrate 6 may be a single layer or multiple layers. The transparent substrate 6 may include a filter layer such as an infrared filter.

A polishing process may be performed on the second surface of the wafer 1 so that the through electrodes (not illustrated) are exposed. A redistribution process may be performed on the second surface of the wafer 1. Numerous conductive ball structures 9 may be formed on redistribution layers disposed on the second surface of the wafer 1. Therefore, the ball structures 9 disposed on the second surface of the wafer 1 may be electrically connected to the image sensing devices of the image sensing regions 3 disposed on the first surface of the wafer 1. Consequently, a chip wafer 10 including wafer level-packaged chips may be formed.

Next, a chip package wafer to form camera modules according to example embodiments will be described with reference to FIGS. 2A through 2C.

Referring to FIG. 2A, the chip wafer 10 shown in FIG. 1 may be cut along the sawing regions (S1 and S2 of FIG. 1) to separate the chip regions CR1, CR2, and CR3 from one another, forming chip packages 12. Chip packages 12 may include chip substrates 1, image sensing regions 3, transparent patterns 6, and ball structures 9.

A chip rearrangement process may be performed to space the chip packages 12 a predetermined distance apart from each other. Each of the chip packages 12 may be positioned on a molding substrate 20 such that the ball structures 9 face upward or away from the molding substrate 20. The chip rearrangement process may include selecting only good chips on the chip wafer 10 and rearranging the good chips.

The chip packages 12 may be rearranged to be spaced apart by a first distance L1 on the molding substrate 20. The molding substrate 20 may have a plurality of molding prominences or protrusions 21 between the chip packages 12. The molding prominences 21 may have a lower height than a thickness of the chip packages 12. In other words, a height h1 of the molding prominence may be less than a height h2 of the chip packages 12.

Referring to FIG. 2B, a molding layer 25 may be formed to fill the spaces between the chip packages 12. As illustrated in FIG. 2C, the molding substrate 20 may be removed to form a chip package wafer including the chip packages 12 connected to each other by the molding layer 25.

The molding layer 25 may include a material capable of blocking light. For example, the molding layer 25 may include a light-blocking material such as epoxy. The molding layer 25 may include slots 25a formed in regions corresponding to the molding prominences 21 of the molding substrate 20.

In other example embodiments, the molding prominences 21 may be omitted on the molding substrate 20. In these embodiments, a laser drilling process, an etching process, or any other slot-forming process may be performed on the molding layer 25 to form the slots 25a.

As illustrated in FIG. 3, in the chip package wafer 200, the molding layer 25 between the chip packages 12 may be cut. As a result, chip structures 14 including the chip packages 12 and molding patterns 13 surrounding sidewalls of the chip packages 12 may be formed. A conductive layer (not illustrated) may be formed to surround the sidewalls of the molding patterns 13 and to extend to a ground structure on a bottom surface of the chip packages 12. The conductive layer (not illustrated) may be formed to prevent a malfunction and/or an image defect of a camera due to an external electromagnetic wave.

Next, lens modules to form camera or photographic modules according to example embodiments will be described with reference to FIGS. 4A and 4B.

Referring to FIG. 4A, a plurality of lens structures 100 spaced apart from each other may be formed. Also, housing structures 150 may be formed to connect the lens structures 100.

The lens structures 100 may be coupled to a pre-existing housing structure 150, or the housing structures 150 may be formed to fill spaces between the lens structures 100. The housing structures 150 may include a material capable of blocking light. Housing prominences or protrusions 152 may be formed on bottom surfaces of the housing structures 150 and may connect to slots 25a in the chip structures 14.

In the example embodiments, combinations of the lens structures 100 and the housing structures 150 are defined as “preliminary lens modules” 400, a lens layer, or a lens structure layer.

As shown in FIG. 4B, the preliminary lens modules 400 shown in FIG. 4A may be separated into lens modules 402. More specifically, referring to FIG. 4B, a plurality of lens modules 402 may be formed by cutting the housing structures 150 between the lens structures 100. The lens modules 402 may include the lens structures 100 and housings 150 surrounding sidewalls of the lens structures 100. Housing prominences 152 may be formed on bottom surfaces of the housings 150.

As shown in FIG. 5, each lens module 402 may include an optical lens 500, a housing 150 including a prominence or protrusion 152, and a fixing ring 520 to stably fixing the optical lens 500 and to the housing 150. The specific shape of the optical lens 500 is not limited to the shape illustrated in FIG. 5, or to the shapes of the lens structures 100 illustrated in FIGS. 4A and 4B, and may be changed into various shapes according to a product for use.

Now, methods of forming camera modules according to example embodiments will be described with reference to FIGS. 6A through 6C.

Referring to FIG. 6A, the chip package wafer 200 illustrated in FIG. 2C may be coupled to the preliminary lens module 400 illustrated in FIG. 4A. For example, the chip package wafer 200 may be positioned on a wafer support 300, and the preliminary lens module 400 may be coupled onto the chip package wafer 200. The housing prominences 152 of the housing structure 150 may be coupled the slots 25a of the molding layer 25 to more stably fix the chip package wafer 200 to the preliminary lens module 400. The housing prominences 152 may be stably fixed in the slots 25a by adhesives (not illustrated).

In some example embodiments, the wafer support 300 may have a protrusion 303 to prevent damage of ball structures 9 of the chip package wafer 200. In other words, the protrusion 303 may be formed at a position corresponding to the molding layer 25 of the chip package wafer 200. Therefore, while the chip package wafer 200 and the preliminary lens module 400 are coupled, damage of the ball structures 9 of the chip package wafer 200 by the wafer support 300 may be prevented.

In other example embodiments, instead of the wafer support 300 shown in FIG. 6A, a wafer support 310 shown in FIG. 6B may be used. In other words, a surface of the wafer support 310 shown in FIG. 6B may be made of a flexible material layer. Therefore, in the surface of the wafer support 310 shown in FIG. 6B, the surface is made of a flexible material layer and thus can prevent damage to the ball structures 9.

In still other example embodiments, instead of the preliminary lens module 400 shown in FIG. 4A, the lens modules 402 described in FIG. 4B may be coupled to the chip package wafer 200. For example, as illustrated in FIG. 6C, the chip package wafer 200 may be positioned on the wafer support 310, and the lens modules 402 may be coupled to the chip package wafer 200. The housing prominences 152 may be coupled and fixed to the slots 25a.

Next, methods of forming camera or photographic modules using the parts described above will be described with reference to FIG. 7 and the drawings described above.

Referring to FIG. 7, in the chip package wafer 200 mounted to the preliminary lens modules 400, as illustrated in FIG. 6A or FIG. 6B, the housing structure 150 between the lens structures 100 may be cut, and the molding layer 25 between the chip packages 12 may be cut. As a result, chip structures 14 including the chip packages 12 and molding patterns 13 surrounding sidewalls of the chip packages 12 may be formed, and lens modules 402 coupled to the chip structures 14 may be formed. Therefore, a plurality of camera, photographic, or image-capture modules 702 may be formed.

A conductive layer (not illustrated) may be formed to cover the sidewalls of the chip structures 14 and the lens modules 402. The conductive layer (not illustrated) may prevent an electro-magnetic interference (EMI) that may be generated in a camera module.

In other example embodiments, the molding layer 25 between the chip packages 12 of the chip package wafer 200 of FIG. 6C may be cut to form camera modules, photographic modules, or image-capture modules 702, as illustrated in FIG. 7.

In still other example embodiments, camera modules 702 may be formed by coupling the lens modules 402, illustrated in FIG. 4B, onto the respective chip structures 14, illustrated in FIG. 3.

As described above, the lens modules 402 may be coupled to an upper part of the respective chip structures 14, to minimize sizes of the camera modules 702. In other words, the lens modules 402 may be coupled to upper parts of the chip structures 14 so as not to extend from the upper parts of the chip structures 14.

Also, at least a part of components constituting the camera modules 702 may be formed at a wafer level, so that productivity can be enhanced. For example, since the chip package wafer 200 described in FIG. 2C and/or the preliminary lens module 400 described in FIG. 4A may be used as components constituting the camera modules, productivity can be improved.

Also, when the chip structure 14 and the lens modules 402 are coupled, the camera modules 702 may have improved durability due to the prominences 152 and the slots 25a.

The inventive concept is not limited to example embodiments described above and may also be embodied as shown in FIGS. 8A through 8C.

Referring to FIG. 8A, a lens wafer 802 may be formed on a chip wafer 10 described in FIG. 1. As a result, a lens chip wafer 800 may be formed that includes the chip wafer 10 and the lens wafer 802.

The lens wafer 802 may include a plurality of optical lenses 806. Because specific shapes of the optical lenses may be changed to various shapes according to the product for use, detailed descriptions will be omitted. Regions between the optical lenses 806 may be defined as sawing regions S1, S2 corresponding to the sawing regions S1 and S2 of the chip wafer 10

Forming the lens chip wafer 800 may include forming the chip wafer 10, forming the lens wafer 802, and coupling the chip wafer 10 and the lens wafer 802 using adhesive agents. In contrast, forming the lens chip wafer 800 may include forming the chip wafer 10 and directly forming the lens wafer 802 on the chip wafer 10.

Referring FIG. 8B, a plurality of lens chip structures 810 may be formed by cutting the lens chip wafer 800 along the sawing regions S1 and S2. Next, a rearrangement process may be performed such that the lens chip structures 810 are spaced apart from each other. Then, through a method similar to the methods of forming the molding layer 25 shown in FIG. 2A through 2C, a molding layer 600 may be formed between the lens chip structures 810.

Referring to FIG. 8C, molding patterns 600a, 600b and 600c surrounding sidewalls of the lens chip structures 810 may be formed by cutting the molding layer between the lens chip structures 810. As a result, camera modules 820 including the lens chip structures 810 and the molding patterns 600a, 600b and 600c may be formed. The molding patterns 600a, 600b and 600c may serve as housings

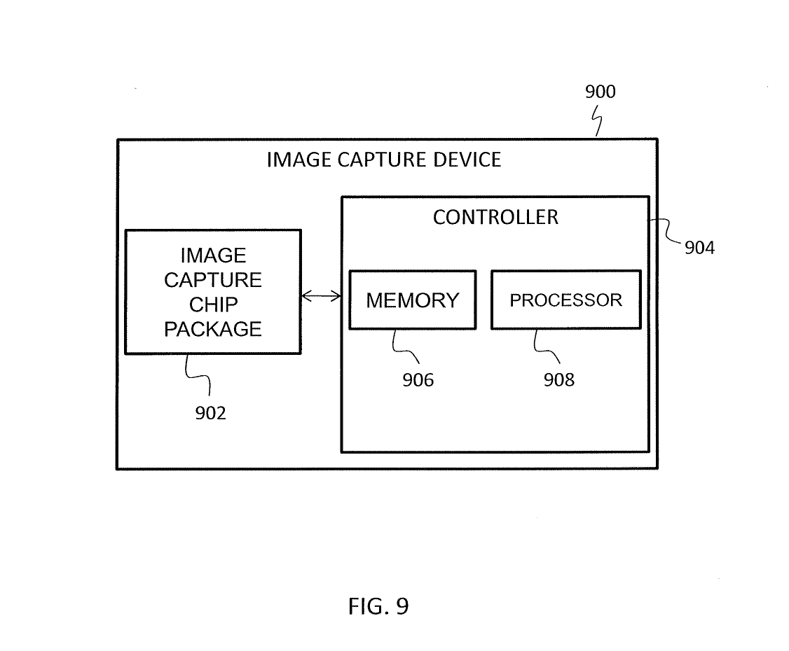

FIG. 9 illustrates an image-capture device 900 including an image-capture semiconductor chip package 902 described above. For example, the semiconductor chip package 902 may include a lens module connected to a chip package. In other words, the semiconductor chip package may correspond to the camera module 702 of FIG. 7, or the camera module 820 of FIG. 8C.

The image-capture device 900 may also include a controller 904 to control operation of the semiconductor chip package 902. The controller 904 may include a processor 908 and memory 906 to control and store image data from the image capture chip package 902. The image-capture device 900 may include additional function units and additional logic circuitry depending on the device. For example, the image-capture device may be a cell phone, portable music/video device, or any other device configured with an image-capture capability. In such a case, the image-capture device 900 may include functional units to make phone calls, play music, access the internet, or to perform any other desired function.

Additional logic, memory, and processing circuitry may be included in the controller 904, or may operate independently of the controller 904. For example, if the image-capture device is a cell phone, the circuitry to make phone calls may share the processor 908 of the controller 904, or the phone call functions may have an independent controller.

According to the example embodiments, a camera module having a minimized size can be provided by coupling a lens module to an upper part of a chip structure.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages. Accordingly, all such modifications are intended to be included within the scope of this general inventive concept as defined in the claims. In the claims, means-plus-function clauses are intended to cover the structures described herein as performing the recited function, and not only structural equivalents but also equivalent structures. Therefore, it is to be understood that the foregoing is illustrative of various example embodiments and is not to be construed as limited to the specific embodiments disclosed, and that modifications to the disclosed embodiments, as well as other embodiments, are intended to be included within the scope of the appended claims.

Although a few embodiments of the present general inventive concept have been illustrated and described, it will be appreciated by those skilled in the art that changes may be made in these embodiments without departing from the principles and spirit of the general inventive concept, the scope of which is defined in the appended claims and their equivalents.

What is claimed is:

1. A photographic module, comprising:
a semiconductor chip including an image-sensing region in a first surface of the semiconductor chip;
a molding material located on lateral sides of the semiconductor chip, the molding material including a first connector; and
a lens structure mounted to the semiconductor chip and including a second connector,
wherein the lens structure is mounted to the semiconductor chip by connecting the first connector to the second connector.

2. The photographic module according to claim 1, further comprising:
a transparent layer located on the first surface of the semiconductor chip, wherein:
the molding material is located on lateral sides of the transparent layer.

3. The photographic module according to claim 1, further comprising:
electrical connection pads on a second surface of the semiconductor chip opposite the first surface.

4. The photographic module according to claim 1, wherein:
the lens structure includes a lens and a housing located on the lateral sides of the lens, the housing including the first connector.

5. The photographic module according to claim 4, wherein one of the first connector and the second connector is a protrusion and the other of the first connector and the second connector is a recess to receive the protrusion.

6. A photographic module, comprising:
a semiconductor chip module layer including a plurality of semiconductor chips separated from each other, each having an image-sensing region in a first surface, and a molding material filling a space between the plurality of semiconductor chips; and
a lens layer mounted onto the semiconductor chip module layer, the lens layer including a plurality of lenses separated by housings,
wherein the lens layer is mounted onto the semiconductor chip module layer such that each semiconductor chip corresponds to a single lens of the lens layer.

7. The photographic module according to claim 6, wherein:
the molding material includes at least one first connector,
the housings include at least one second connector, and
mounting the lens layer to the semiconductor chip module layer includes connecting the at least one first connector to the at least one second connector.

8. The photographic module according to claim 10, wherein each semiconductor chip corresponds to a separate at least one first connector and a separate at least one second connector.

9. An image-capture device, comprising:
a semiconductor chip including an image-sensing region in a first surface of the semiconductor chip;
a molding material located on lateral sides of the semiconductor chip, the molding material including a first connector;
a lens structure mounted to the semiconductor chip and including a second connector connected to the first connector; and
a controller to capture an image received by the image-sensing region.

10. The image-capture device according to claim 9, wherein:
the controller includes at least one memory device to store data corresponding to the image received by the image-sensing region and at least one processor to control at least one of the semiconductor chip and the memory device.
